(19) United States
(12) Patent Application Publication
(10) Pub. No.: US 2026/0026386 A1
(43) Pub. Date: Jan. 22, 2026

(54) UNDERFILL DISPENSING SYSTEM

(71) Applicant: SAMSUNG ELECTRONICS CO., LTD., SUWON-SI (KR)

(72) Inventor: Donggyu Kim, Suwon-si (KR)

(21) Appl. No.: 19/188,310

(22) Filed: Apr. 24, 2025

(30) Foreign Application Priority Data
Jul. 19, 2024 (KR) 10-2024-0095621

(51) Int. Cl. H01L 23/00

(52) U.S. Cl. CPC H01L 24/75; H01L 2224/75251; H01L 2224/75611; H01L 2224/759; H01L 2924/37

(57) ABSTRACT

An underfill dispensing system includes a substrate table configured to support a substrate including a plurality of bonding areas for mounting a plurality of semiconductor chips, a heating structure disposed on an upper surface of the substrate table and including a plurality of heating blocks, a dispensing head configured to dispense underfill to a plurality of bonding areas of the substrate, above the substrate table, an imaging device, and a control unit configured to control the heating structure and the dispensing head. The imaging device is configured to image at least one of the substrate and the plurality of semiconductor chips to generate an image. The controller is configured to control the plurality of heating blocks independently of one another based on the image.

### CROSS-REFERENCE TO RELATED APPLICATION(S)

This U.S. patent application claims priority under 35 USC 119(a) to Korean Patent Application No. 10-2024-0095621 filed on Jul. 19, 2024 in the Korean Intellectual Property Office, the disclosure of which incorporated by reference in its entirety.

### 1. TECHNICAL FIELD

The present inventive concept is directed to an underfill dispensing system.

### 2. DISCUSSION OF RELATED ART

An underfill dispensing process in semiconductor manufacturing starts by placing a semiconductor chip, such as a flip-chip, face-down onto a substrate or circuit board, aligning the chip's electrical connections (bumps) with the substrate's pads. A specialized epoxy or polymer resin, known as underfill, is then applied around the chip. This underfill is drawn into the small gap between the chip and the substrate by capillary action. Once the gap is completely filled, the underfill is cured with heat to solidify, forming a robust bond that helps distribute stress and protect the chip from environmental and mechanical damage.

However, challenges arise when the arrangement of bumps is not uniform. In areas where bump density is high, underfill may flow slowly, which can decrease the productivity of the process. Conversely, in areas with low bump density, the underfill may flow too quickly, potentially leading to the formation of voids within the underfill. These inconsistencies can impact the overall quality and reliability of the semiconductor device.

### SUMMARY

Example embodiments provide an underfill dispensing system including a heating structure.

According to an example embodiment, an underfill dispensing system includes a substrate table, a heating structure, a dispensing head, a memory, a processor, an image device and a control unit. The substrate table is configured to support a substrate including a plurality of bonding areas for mounting a plurality of semiconductor chips are mounted. The heating structure is disposed on an upper surface of the substrate table and includes a plurality of heating blocks. The dispensing head is configured to dispense underfill to a plurality of bonding areas of the substrate, above the substrate table. The memory stores a program. The processor is connected to the memory. The imaging device is connected to the processor. The control unit is configured to control the heating structure, the dispensing head, and the processor. The imaging device is configured to image at least one of the substrate and the plurality of semiconductor chips to generate an image. The control unit is configured to control the plurality of heating blocks independently of one another.

According to an example embodiment, an underfill dispensing system includes a substrate table, a heating structure, a dispensing head, a processor, a first imaging device, a second imaging device, and a control unit. The substrate table is configured to support a substrate including a plurality of bonding areas for mounting a plurality of semiconductor chips. The heating structure is disposed on an upper surface of the substrate table and includes a plurality of heating blocks. The dispensing head is configured to dispense underfill to a plurality of bonding areas of the substrate, above the substrate table. The first imaging device is connected to the processor and configured to capture a first image of the substrate. The second imaging device is connected to the processor and configured to capture a second image of at least one of the plurality of semiconductor chips. The control unit is configured to control the heating structure, the dispensing head, and the processor. The processor is configured to generate temperature control data based on the first image and the second image. The control unit is configured to control the plurality of heating blocks independently from one another using the temperature control data.

According to example embodiment, an underfill dispensing system includes a substrate table, a heating structure, a dispensing head, a processor, an imaging device and a control unit. The substrate table is configured to support a substrate including a plurality of bonding areas for mounting a plurality of semiconductor chips are mounted. The heating structure is disposed on an upper surface of the substrate table and includes a plurality of heating blocks arranged in a grid pattern. The dispensing head is configured to dispense underfill to a plurality of bonding areas of the substrate, above the substrate table. The imaging device is connected to the processor. The control unit is configured to control the heating structure, the dispensing head, and the processor. The dispensing head includes a dispensing nozzle for discharging the underfill, an underfill reservoir configured to supply the underfill to the dispensing nozzle, and a nozzle movement assembly configured to move the dispensing nozzle. The imaging device is configured to image at least one of the substrate and the plurality of semiconductor chips to generate an image. The control unit controls the processor to generate temperature control data based on the image and controls the plurality of heating blocks independently from each other using the temperature control data.

### BRIEF DESCRIPTION OF DRAWINGS

The above and other aspects and features of the present inventive concept will be more clearly understood from the following detailed description, taken in conjunction with the accompanying drawings, in which:

FIG. 1 is a schematic perspective view of an underfill dispensing system according to an example embodiment;

FIG. 2 is a block diagram of components of an underfill dispensing system according to an example embodiment;

FIG. 3 is a plan view of a heating structure and a substrate illustrated in FIG. 1;

FIG. 4 illustrates a bonding area of a substrate illustrated in FIG. 2;

FIG. 5A is a schematic plan view of a heating block according to an example embodiment;

FIGS. 5B and 5C illustrate control flows of heating blocks according to example embodiments;

FIGS. 5D and 5E are schematic perspective views of a heating block according to example embodiments;

FIG. 6 is a flow chart illustrating an underfill dispensing method according to an example embodiment;

FIGS. 7 to 11 are cross-sectional views illustrating process sequences to illustrate an underfill dispensing method and a semiconductor package manufacturing method according to example embodiments;

FIG. 12 is a schematic perspective view of an underfill dispensing system according to an example embodiment;

FIG. 13 is a flow chart illustrating an underfill dispensing method according to an example embodiment; and

FIG. 14 is a schematic perspective view of an underfill dispensing system according to an example embodiment.

### DETAILED DESCRIPTION

Hereinafter, example embodiments will be described with reference to the accompanying drawings.

Embodiments of the invention concept introduce an innovative solution to address the challenges associated with uneven underfill dispensing in semiconductor manufacturing. The concept involves a heating structure positioned beneath the substrate, composed of multiple heating blocks that may be smaller than the semiconductor chip. This design allows for localized heating of the bump structures connected to the chip. An imaging device captures images of either the substrate or the semiconductor chip to analyze the pattern of the upper pad or the chip's bump structure. Utilizing a machine learning model, temperature control data may be generated based on these images. This data guides the precise heating of the blocks, applying higher temperatures in areas with dense bump patterns to accelerate underfill flow, and lower temperatures in less dense areas to prevent the formation of voids. This targeted approach ensures more uniform underfill distribution, enhancing the efficiency and quality of the semiconductor assembly process.

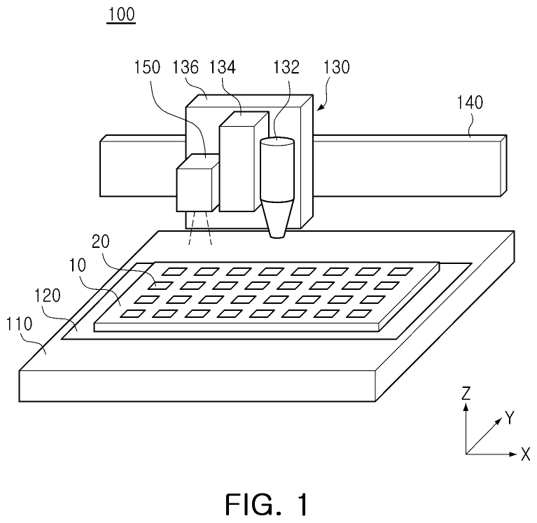

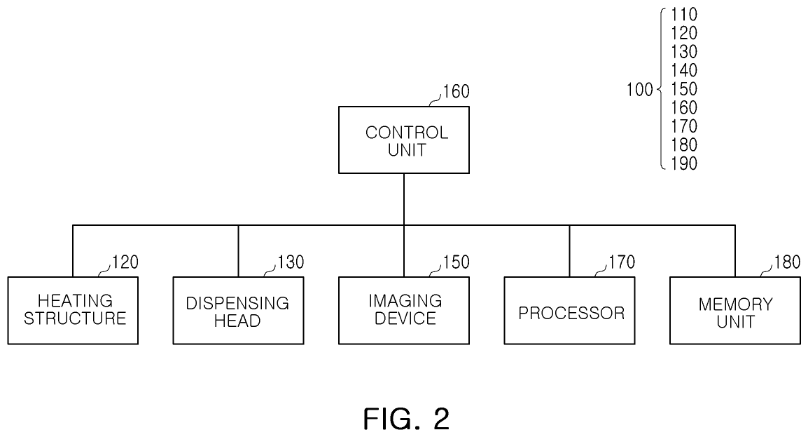

FIG. 1 is a schematic perspective view of an underfill dispensing system according to an example embodiment. FIG. 2 is a block diagram of components of an underfill dispensing system according to an example embodiment.

Referring to FIGS. 1 and 2, an underfill dispensing system 100 according to an example embodiment includes a substrate table 110, a heating structure 120, a dispensing head 130, a transport guide 140, an imaging device 150, a control unit 160 (e.g., a control circuit), a processor 170, and a memory unit 180 (e.g., a memory device).

The substrate table 110 may be positioned below the substrate 10 to load the substrate 10. For example, the substrate 10 may be loaded onto the substrate table 110, and after the underfill dispensing process has completed, the substrate 10 may be unloaded from the substrate table 110.

The heating structure 120 may be placed on the substrate table 110 and may heat the substrate 10 before performing the underfill dispensing process. For example, the heating structure 120 may be placed between the substrate table 110 and the substrate 10. The heating structure 120 may locally heat the substrate 10 to control the viscosity of an underfill solution. For example, the heating structure 120 may heat a first region of the substrate 10 relatively high to lower the viscosity of the underfill solution in the first region, or may heat a second region of the substrate 10 relatively low to increase the viscosity of the underfill solution in the second region.

The heating structure 120 may be connected to the control unit 160. For example, the heating structure 120 may be commutatively connected to the control unit 160, allowing it to transmit and receive both electrical and data signals. This connection facilitates the synchronization and management of heating activities based on the control inputs and feedback received from the control unit 160.

The dispensing head 130 may be disposed above the substrate 10 and the substrate table 110, and may be configured to spray an underfill solution toward the substrate 10. The dispensing head 130 may include a dispensing nozzle 132, an underfill solution supply device 134 (e.g., an underfill reservoir), and a transport device 136 (e.g., a nozzle movement assembly). The dispensing nozzle 132 may receive the underfill solution from the underfill solution supply device 134 and may discharge the underfill solution toward the substrate 10. For example, the dispensing nozzle 132 may be designed to draw the underfill solution from the underfill solution supply device 134 and dispense it onto the substrate 10. The dispensing nozzle 132 may discharge the underfill solution using a pump that uses a jet pump method, a cylinder method, a ball screw method, or the like. The underfill solution may be stored within the underfill solution supply device 134.

The dispensing head 130 may be transferred horizontally above the substrate table 110 along the transport guide 140. For example, the dispensing head 130 can move horizontally over the substrate table 110, guided by the transport guide 140. The transport device 136 of the dispensing head 130 may be connected to the transport guide 140 and move in the X-direction along the transport guide 140. For example, the transport device 136, part of the dispensing head 130, is attached to the transport guide 140 and can move in the X-direction along the transport guide 140. The underfill dispensing system 100 may further include a transport guide extending in the Y-direction, allowing the dispensing head 130 to move in the Y-direction or vertically.

The dispensing head 130 may be connected to the control unit 160. For example, the dispensing nozzle 132, the underfill solution supply device 134, and the transport device 136 of the dispensing head 130 may respectively be commutatively connected to the control unit 160, enabling them to send and receive electrical signals and/or data signals.

The imaging device 150 may be configured to capture images of a substrate 10 loaded on the substrate table 110. For example, the imaging device 150 may be configured to image a plurality of bonding areas of the substrate 10. In an example embodiment, the imaging device 150 may be a camera including a charge coupled device (CCD) image sensor or a complementary metal oxide semiconductor (CMOS) image sensor.

In an example embodiment, the imaging device 150 is mounted on the dispensing head 130. The imaging device 150 may be mounted on the transport device 136 and may be moved horizontally above the substrate 10 while facing the substrate 10. For example, the imaging device 150 may be moved horizontally across the top of the substrate 10, with its imaging components directed towards the substrate 10. In an example embodiment, the imaging device 150 is placed on the substrate 10 but is mounted on a structure other than the dispensing head 130.

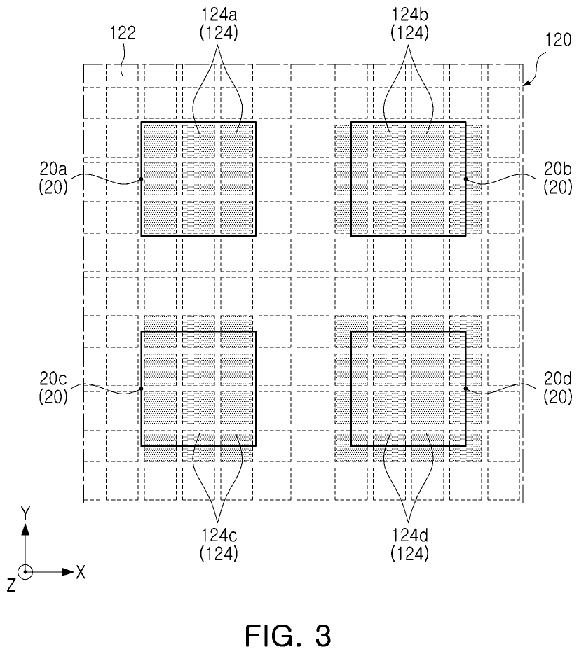

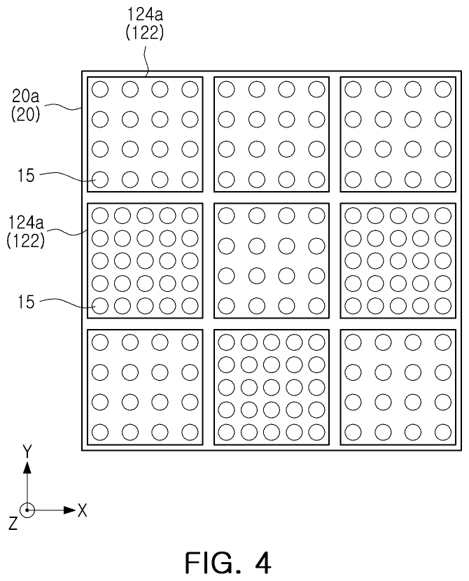

FIG. 3 is a plan view of the heating structure and substrate illustrated in FIG. 1. FIG. 4 illustrates the bonding area of the substrate illustrated in FIG. 2.

Referring further to FIG. 3 and FIG. 4, the substrate 10 may include bonding areas 20, and the heating structure 120 may include heating blocks 122. The heating blocks 122 may be individual heating elements that generate heat. The bonding areas 20 may refer to areas on the substrate 10 where semiconductor chips are bonded. For example, upper pads 15 electrically connected to the semiconductor chips may be disposed on the upper surface of the substrate 10, and areas where the upper pads 15 are disposed and vertically overlap the semiconductor chips may be referred to as bonding areas 20.

The bonding areas 20 may be disposed at regular intervals from each other on the substrate 10 and may have the same size. In an example embodiment, the bonding areas 20 include a first bonding area 20a, a second bonding area 20b, a third bonding area 20c, and a fourth bonding area 20d.

The heating blocks 122 may be arranged at a constant pitch. For example, the heating blocks 122 may have grid patterns arranged at a constant pitch in the X-direction and the Y-direction. Although the respective heating blocks 122 are illustrated as having a square shape, the shape is not limited thereto. In example embodiments, the heating blocks 122 may have various shapes such as a triangle, a rectangle, a polygon, a circle, or an oval when viewed in a plan view. In an embodiment, the size of each of the heating blocks 122 is smaller than the size of the bonding area 20. In addition, the size of each of the heating blocks 122 may be smaller than the size of the semiconductor chip 30 described below.

The heating blocks 122 may be controlled by the control unit 160 to heat the substrate 10. In an example embodiment, the heating blocks 122 are respectively independently controlled. For example, at least some of the heating blocks 122 among the heating blocks 122 may be heated to different temperatures. Alternatively, at least some of the heating blocks 122 among the heating blocks 122 may start or end heating at different times.

In an example embodiment, some of the heating blocks 122 among the heating blocks 122 may vertically overlap the bonding areas 20. The heating block 122 that at least partially vertically overlaps the bonding areas 20 may be referred to as a target block 124 (or a target heating block). The target blocks 124 may respectively be independently controlled by the control unit 160. For example, at least some of the target blocks 124 may be heated to different temperatures.

In an example embodiment, the first target blocks 124a, the second target blocks 124b, the third target blocks 124c, and the fourth target blocks 124d are vertically overlapped with the first bonding area 20a, the second bonding area 20b, the third bonding area 20c, and the fourth bonding area 20d, respectively. In an example embodiment, the number of target blocks 124 corresponding to each of the bonding areas 20 may be different. For example, the first bonding area 20a may be vertically overlapped with nine first target blocks 124a. The second bonding area 20b and the third bonding area 20c may vertically overlap twelve second target blocks 124b and third target blocks 124c, respectively. The fourth bonding area 20d may vertically overlap sixteen fourth target blocks 124d. Respective target blocks 124 may partially or completely overlap the corresponding bonding area 20. For example, the first target blocks 124a may respectively completely overlap the first bonding area 20a in the vertical direction. Some of the second target blocks 124b may partially overlap the second bonding area 20b.

As illustrated in FIG. 4, upper pads 15 may be disposed in the first bonding area 20a, and

the upper pads 15 may vertically overlap the corresponding first target blocks 124a. In an example embodiment, the upper pads 15 are not disposed at a constant pitch or in a constant pattern. For example, the number of upper pads 15 corresponding to the respective first target blocks 124a may be different. For example, some of the first target blocks 124a may vertically overlap sixteen upper pads 15, and some of the first target blocks 124a may vertically overlap 25 upper pads 15. However, the number and arrangement of the upper pads 15 are examples and are not limited thereto. In an example embodiment, some of the upper pads 15 do not vertically overlap the first target blocks 124a, or vertically overlap a plurality of first target blocks 124a.

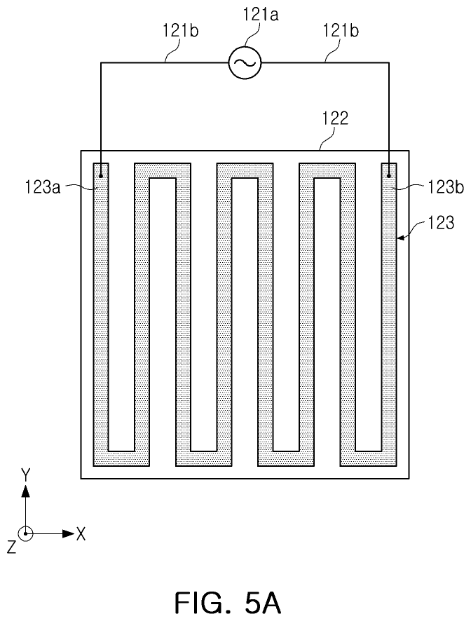

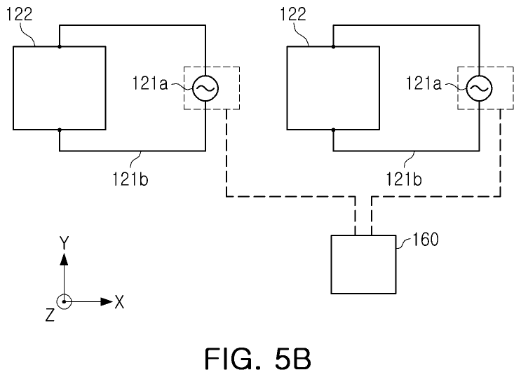

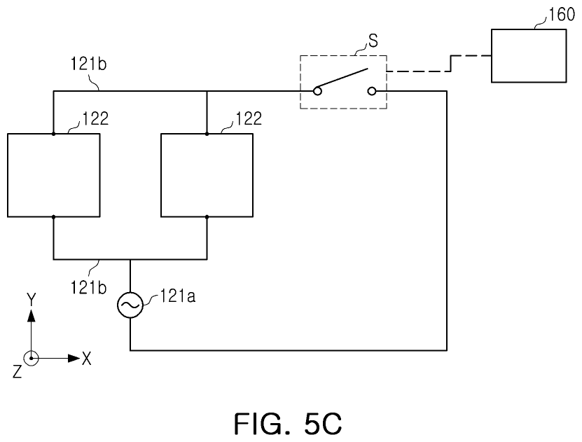

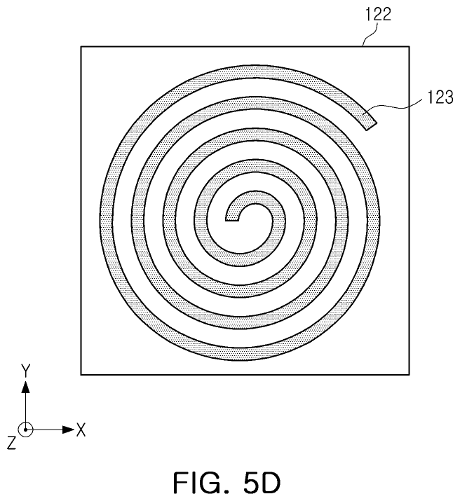

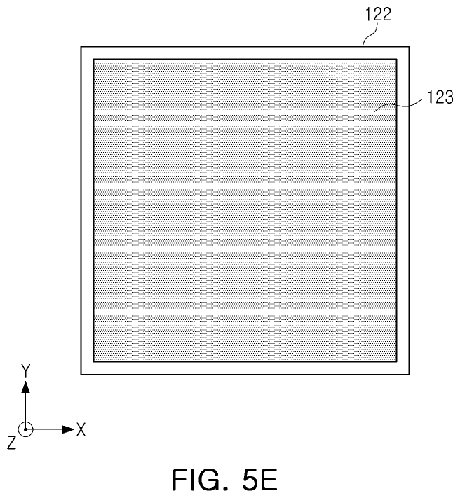

FIG. 5A is a schematic plan view of a heating block according to an example embodiment.

With further reference to FIG. 5A, the heating block 122 may include a metal structure 123, and the heating structure 120 may further include a power source 121a and wires 121b that supply power to the heating blocks 122. The power source 121a may supply alternating current (AC) power, but is not limited thereto. In an example embodiment, the power source 121a may supply direct current (DC) power.

The metal structure 123 may be a resistive element that generates heat when current flows through it. For example, the metal structure 123 may extend in a horizontal direction and may include a first end 123a and a second end 123b. The first end 123a and the second end 123b may be connected to the power source 121a by the wires 121b, respectively. The power source 121a, the wires 121b, the first end 123a, and the second end 123b may form a heating circuit. When the current supplied by the power source 121a flows between the first end 123a and the second end 123b along the heating circuit, the metal structure 123 may be heated, and the substrate 10 may be heated. For example, as the current from power source 121a travels from the first end 123a to the second end 123b through this circuit, it heats up the metal structure 123, which in turn heats the substrate 10. The metal structure 123 may include a series of interconnected segments or coils spanning between the first end 123a and the second end 123b.

FIGS. 5B and 5C illustrate control flows of heating blocks according to example embodiments.

Referring to FIG. 5B, in an example embodiment, the heating blocks 122 may form an independent heating circuit and may be independently controlled. For example, the heating blocks 122 may be respectively connected to different power sources 121a. Each power source 121a may be controlled by the control unit 160. The control unit 160 may manage each power source 121a, controlling the timing of their activation and deactivation. The control unit 160 may control the amount of current provided to the heating blocks 122 by the respective power sources 121a. The heating blocks 122 may be controlled independently and may thus be heated to different temperatures.

Referring to FIG. 5C, in an example embodiment, the heating blocks 122 may form independent heating circuits and may be controlled independently. For example, the heating blocks 122 are connected to the same power source 121a, but a switching element(S) may be placed between respective heating blocks 122 and the power source 121a. For example, while FIG. 5C illustrates a switching element(S) between the heating blocks 122 and the control unit 160, a first switching unit may be placed on a first wire connecting the first heating block 122 to the power source 121 and a second switching unit may be placed on a second wire connecting the second heating block 122 to the power source 121. The control unit 160 may control the switch elements(S), and respective heating blocks 122 may be supplied with current according to the operation of the switch elements(S). In an example embodiment, elements such as variable resistors for controlling the current supplied to the heating blocks 122 may be further disposed between respective heating blocks 122 and the power source 121a. The heating blocks 122 may be independently controlled and may thus be heated to different temperatures.

Referring again to FIGS. 1 to 4, the control unit 160 may be configured to control the heating structure 120, the dispensing head 130, the imaging device 150, the processor 170, and the memory unit 180. The control unit 160 may be commutatively connected to the heating structure 120, the dispensing head 130, the imaging device 150, the processor 170, and the memory unit 180, and may transmit and receive electrical signals and/or data signals.

As described above, the control unit 160 may independently control the heating blocks 122 of the heating structure 120. The control unit 160 may independently control the target blocks 124 that vertically overlap the bonding areas 20 among the heating blocks 122. In an example embodiment, the control unit 160 may also independently control the temperature of the heating blocks 122 other than the target blocks 124.

The control unit 160 may control the dispensing head 130 to sequentially dispense the underfill solution onto the bonding areas 20 of the substrate 10. For example, the transport device 136 may be controlled by the control unit 160 to move above the substrate 10, and the dispensing nozzle 132 may dispense the underfill solution. For instance, the control unit 160 might direct the transport device 136 to position itself over the substrate 10, enabling the dispensing nozzle 132 to release the underfill solution.

In an example embodiment, the control unit 160 may control the imaging device 150 to image the substrate 10. For example, the imaging device 150 may capture images of the bonding areas 20 of the substrate 10. The processor 170 may use these images to compare the positions of the heating blocks 122 of the heating structure 120, which are stored in the memory unit 180, with the positions of the bonding areas 20 depicted in the images. This comparison helps to identify which of the heating blocks 122 vertically align with over overlap with the bonding areas 20. As described above, the heating blocks 122 that vertically align or overlap the bonding areas 20 may be referred to as target blocks 124.

The control unit 160 may control the processor 170 to generate temperature control data based on the image. For example, the processor 170 may generate temperature control data based on the shape of the upper pads 15 of the substrate 10 illustrated in the image, the pattern density, the spacing between the upper pads 15, or the like.

The processor 170 may use the program and machine learning model stored in the memory unit 180 to generate the temperature control data. The program stored in the memory unit 180 may instruct that the target block 124 with a relatively high pattern density of the corresponding upper pads 15 be heated to a relatively high temperature, and instruct that the target block 124 with a relatively low pattern density of the corresponding upper pads 15 be heated to a relatively low temperature. In an area where the pattern density of the upper pads 15 is relatively high, the underfill solution may flow relatively slowly, and in an area in which the pattern density of the upper pads 15 is relatively low, the underfill solution may flow relatively quickly.

According to an example embodiment, since the temperature of the underfill solution is relatively high in an area where the pattern density of the upper pads 15 is relatively high, the viscosity of the underfill solution may be lowered to increase the flowability. Therefore, the underfill dispensing process time may be shortened, and productivity may be increased. According to an example embodiment, since the temperature of the underfill solution is relatively lowered in an area where the pattern density of the upper pads 15 is relatively low, the viscosity of the underfill solution may be increased to reduce the flowability. Accordingly, the underfill solution may quickly flow in an area where the pattern density of the upper pads 15 is relatively low, thereby reducing or preventing voids from occurring in the underfill solution.

The machine learning model stored in the memory unit 180 may be generated using a neural network, a support vector machine (SVM), a multi-layer perception (MLP), deep learning, and the like. The machine learning model may be trained by incorporating weights derived from simulation results, taking into account factors such as the time required for the underfill dispensing process and the occurrence of voids. These simulations may use variables such as the density and spacing of the upper pads 15 of the substrate 10, the bump structure of the semiconductor chip, as well as the temperature and viscosity of the underfill solution. The processor 170 may more accurately calculate the temperature control data of each target block 124 using the machine learning model.

FIGS. 5D and 5E are schematic plan views of heating blocks according to example embodiments.

Referring to FIG. 5D, in an example embodiment, when viewed in the plan view, the metal structure 123 of the heating block 122 has a spiral shape. For example, the heating block 122 may have a structure in which concentric circles are connected. For example, the metal structure 123 may have a spiral shape, where a single wire begins at a first end and curves inward in a circular pattern, coiling around itself multiple times until it terminates at a second end at the center of the spiral.

Referring to FIG. 5E, in an example embodiment, when viewed in the plan view, the metal structure 123 of the heating block 122 has a quadrangular shape. However, the present inventive concept is not limited thereto, and in example embodiments, the metal structure 123 may have various shapes extending in the horizontal direction.

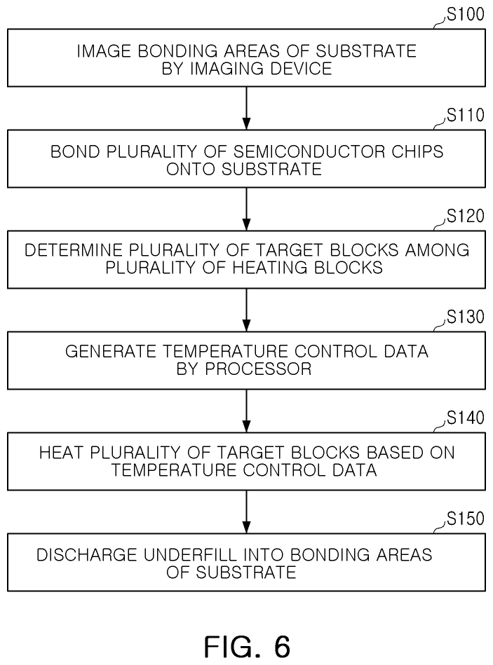

FIG. 6 is a flow chart illustrating an underfill dispensing method according to an example embodiment.

Referring to FIG. 6, an underfill dispensing method according to an example embodiment may include an imaging device 150 imaging bonding areas 20 of a substrate 10 (S100), bonding a plurality of semiconductor chips on the substrate 10 (S110), determining a plurality of target blocks 124 among a plurality of heating blocks 122 (S120), a processor 170 generating temperature control data (S130), heating the plurality of target blocks 124 based on the temperature control data (S140), and discharging underfill into the bonding areas 20 of the substrate 10 (S150).

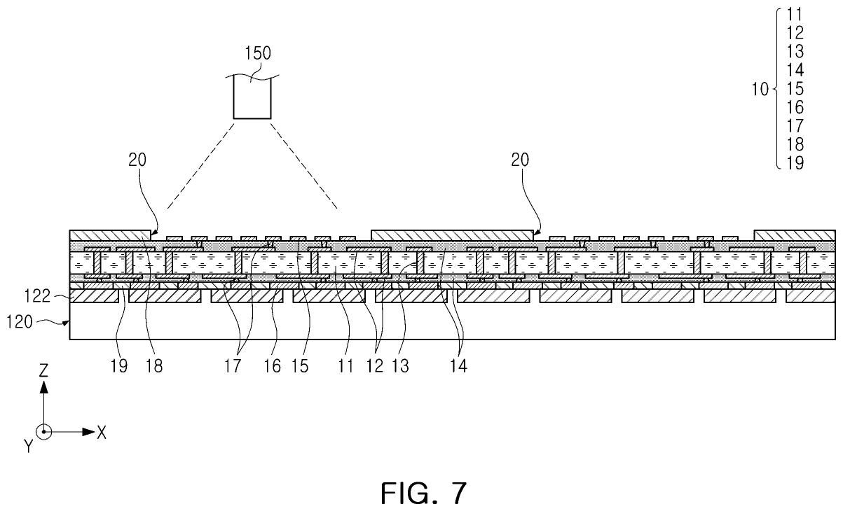

FIGS. 7 to 11 are cross-sectional views illustrating the process sequence illustrating an underfill dispensing method and a semiconductor package manufacturing method according to an example embodiment.

Referring to FIGS. 6 and 7, a substrate 10 may be loaded on a heating structure 120. The substrate 10 may include an insulating layer 11, an interconnection layer 12, a via 13, a protective layer 14, an upper pad 15, a lower pad 16, a via 17, an upper protective layer 18, and a lower protective layer 19. In an example embodiment, the substrate 10 may be a semiconductor package substrate such as a printed circuit board (PCB), an interposer substrate, a ceramic substrate, or a tape interconnection board. In an example embodiment, the substrate 10 may be a printed circuit board. For example, the insulating layer 11 of the substrate 10 may include a thermosetting resin such as an epoxy resin, a thermoplastic resin such as a polyimide, or a photosensitive insulating layer. For example, the insulating layer 11 may include materials such as prepreg, Ajinomoto Build-up Film (ABF), FR-4, Bismaleimide Triazine (BT), Photo Imageable Dielectric (PID) resin, or the like. The insulating layer 11 may be formed using, for example, a copper clad laminate (CCL), an unclad copper clad laminate (Unclad CCL), a glass substrate, a ceramic substrate, or the like. According to some example embodiments, the substrate 10 does not include the insulating layer 11.

The interconnection layers 12 may be disposed on the lower surface and the upper surface of the insulating layer 11. The vias 13 may extend vertically through the insulating layer 11. The interconnection layers 12 may be electrically connected to each other through the vias 13. The interconnection layer 12 may include, for example, a metal material including copper (Cu), aluminum (Al), silver (Ag), tin (Sn), gold (Au), nickel (Ni), lead (Pb), titanium (Ti), or alloys thereof. The lower interconnection layer 12 may include, for example, a ground pattern, a power pattern, and a signal pattern. The signal pattern may serve as a pathway for transmitting and receiving various signals, such as data signals.

The via 13 is electrically connected to the interconnection layer 12 and may include a signal via, a ground via, and a power via. The via 13 may include, for example, a metal material including copper (Cu), aluminum (Al), silver (Ag), tin (Sn), gold (Au), nickel (Ni), lead (Pb), titanium (Ti), or alloys thereof. The via 13 may be a filled via in which a metal material is filled inside the via hole or a conformal via in which a metal material is formed along the inner wall of the via hole. The via 13 may be integrally formed with the interconnection layer 12, but the example embodiments are not limited thereto.

The protective layer 14 may be disposed on the lower and upper surfaces of the insulating layer 11 and may cover the interconnection layers 12. The upper pad 15 and the lower pad 16 may be disposed on the upper and lower surfaces of the substrate 10, respectively. The upper pad 15 and the lower pad 16 may be disposed on the protective layer 14, respectively. The upper pad 15 and the lower pad 16 may be electrically connected to the corresponding interconnection layer 12 through the vias 17. The upper pad 15, the lower pad 16, and the via 17 may each include a metal material including copper (Cu), aluminum (Al), silver (Ag), tin (Sn), gold (Au), nickel (Ni), lead (Pb), titanium (Ti), or alloys thereof.

The upper protective layer 18 and the lower protective layer 19 may be respectively disposed on the lower surface and the upper surface of the substrate 10 and may cover the protective layer 14. The upper protective layer 18 may partially cover the protective layer 14. For example, the upper protective layer 18 may leave the upper pads 15 uncovered, allowing the upper pads 15 to remain exposed. In an example embodiment, the side surfaces of the upper pads 15 may be covered by the upper protective layer 18. The lower protective layer 19 may cover the side surfaces of the lower pads 16, while the lower surfaces of the lower pads 16 remain exposed.

The protective layer 14, the upper protective layer 18, and the lower protective layer 19 may include an insulating resin and an inorganic filler. For example, the protective layer 14, the upper protective layer 18, and the lower protective layer 19 may include ABF, but is not limited thereto. The protective layer 14, the upper protective layer 18, and the lower protective layer 19 may include a photosensitive insulating material (PID) or an insulating polymer, for example, Photosensitive Polyimide (PSPI).

The imaging device 150 may image the bonding areas 20 of the substrate 10 (S100) to generate images of the bonding areas 20. In this case, the bonding areas 20 may mean areas that are exposed and not covered by the upper protective layer 18. The images may be stored in the memory unit 180 and may be used by the processor 170 to generate temperature control data.

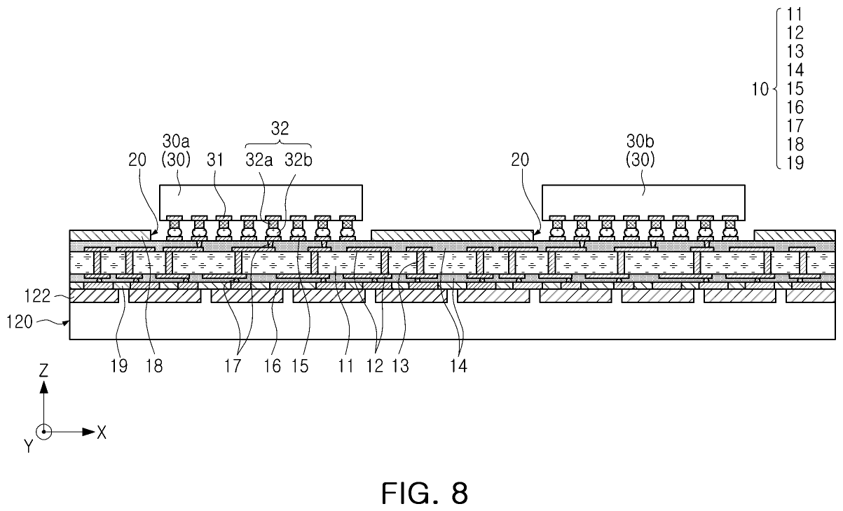

Referring to FIG. 6 and FIG. 8, a plurality of semiconductor chips 30 may be bonded on a substrate 10 (S110). For example, a first semiconductor chip 30a and a second semiconductor chip 30b may be respectively placed on a bonding area 20 and electrically connected to upper pads 15.

The semiconductor chip 30 may be a logic chip or a memory chip. The logic chip may include a microprocessor, an analog device, or a digital signal processor. The memory chip may include a volatile memory chip such as a Dynamic Random Access Memory (DRAM), a Static Random Access Memory (SRAM), or a nonvolatile memory chip such as a Phase-change Random Access Memory (PRAM), a Magnetoresistive Random Access Memory (MRAM), a Ferroelectric Random Access Memory (FeRAM), or a Resistive Random Access Memory (RRAM).

The first semiconductor chip 30a and the second semiconductor chip 30b may be bonded on the bonding area 20 by a flip chip bonding method. For example, the first semiconductor chip 30a and the second semiconductor chip 30b may be connected to the upper pads 15 of the substrate by bump structures 32 disposed on the lower surface thereof. For example, the semiconductor chip 30 may include a chip pad 31 connected to the bump structure 32. The chip pad 31 may be disposed on the lower surface of the semiconductor chip 30 and may be in contact with a corresponding bump structure 32. For example, the bump structure 32 may have a flip-chip connection structure having a grid array such as a solder ball, a conductive bump, a pin grid array, a ball grid array, or a land grid array.

The bump structures 32 may include a first portion 32a that is in contact with the chip pads 31 and a second portion 32b that connects the first portion 32a and the upper pad 15. For example, the first portion 32a may be a metal post portion, and the second portion 32b may be a solder portion including a low-melting-point metal, but is not limited thereto. According to an example embodiment, the bump structures 32 may include only the second portion 32b. The low melting point metal may include tin (Sn), indium (In), bismuth (Bi), antimony (Sb), copper (Cu), silver (Ag), zinc (Zn), lead (Pb), or alloys (for example, Sn—Ag—Cu) thereof.

Before the heating structure 120 is heated, the processor 170 may determine a plurality of target blocks 124 among a plurality of heating blocks 122 (S120). For example, the positions of the bonding areas 20 of the substrate 10 stored in the memory unit 180 and the images captured by the imaging device 150 may be compared to determine the heating blocks 122 that vertically overlap the bonding areas 20. The heating blocks 122 that vertically overlap the bonding areas 20 may be referred to as target blocks 124.

The processor 170 may generate temperature control data based on the images (S130). For example, the processor 170 may generate temperature control data based on the pattern density or spacing of the upper pads 15 in the images corresponding to the determined respective target blocks 124. The processor 170 may use a program and machine learning model stored in the memory unit 180 to generate the temperature control data. For example, if the pattern density of the upper pads 15 corresponding to the target block 124 is relatively high, the program may instruct that the target block 124 be heated to a relatively high temperature. If the pattern density of the upper pads 15 corresponding to the target block 124 is relatively low, the program may instruct that the target block 124 be heated to a relatively low temperature.

In an example embodiment, determining a plurality of target blocks 124 (S120) and generating temperature control data (S130) may be preceded by bonding a plurality of semiconductor chips 30 on the substrate 10 (S110).

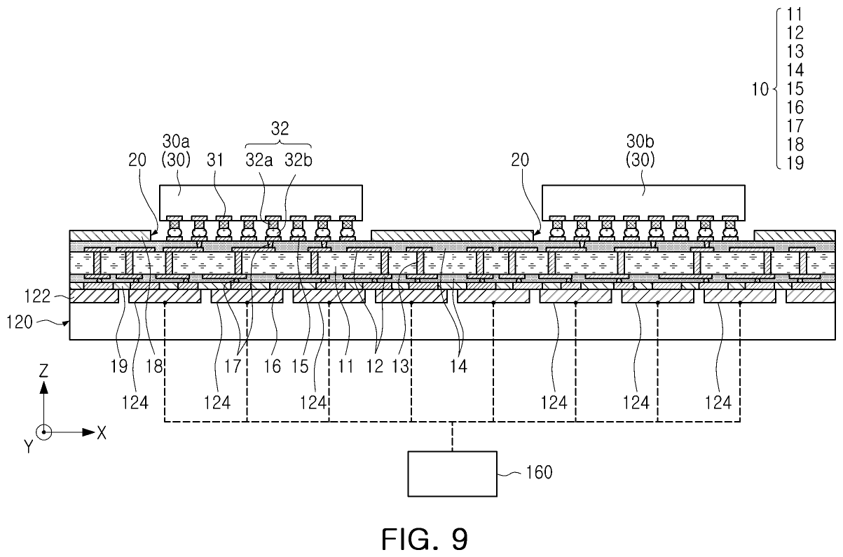

Referring to FIGS. 6 and 9, a plurality of target blocks 124 may be heated based on temperature control data (S140). For example, the control unit 160 may receive the temperature control data from the processor 170 and control the plurality of target blocks 124 to be heated based on the temperature control data. As described above, the plurality of target blocks 124 may be independently controlled, and some of the target blocks 124 among the plurality of target blocks 124 may be heated to different temperatures.

In an example embodiment, some of the heating blocks 122 surrounding the target blocks 124 may also be heated. The heating blocks 122 surrounding the target blocks 124 may be referred to as ‘peripheral blocks’. The peripheral blocks may be directly adjacent to some of the target blocks. The processor 170 may be further configured to compare the images captured by the imaging device 150 with the positions of the bonding areas 20 of the substrate 10 stored in the memory unit 180 to determine the peripheral blocks that do not vertically overlap the bonding areas 20. The peripheral blocks may be heated to a constant temperature and may be heated to the same temperature. In an example embodiment, the peripheral blocks may be heated to different temperatures. In an example embodiment, the peripheral blocks may not be heated.

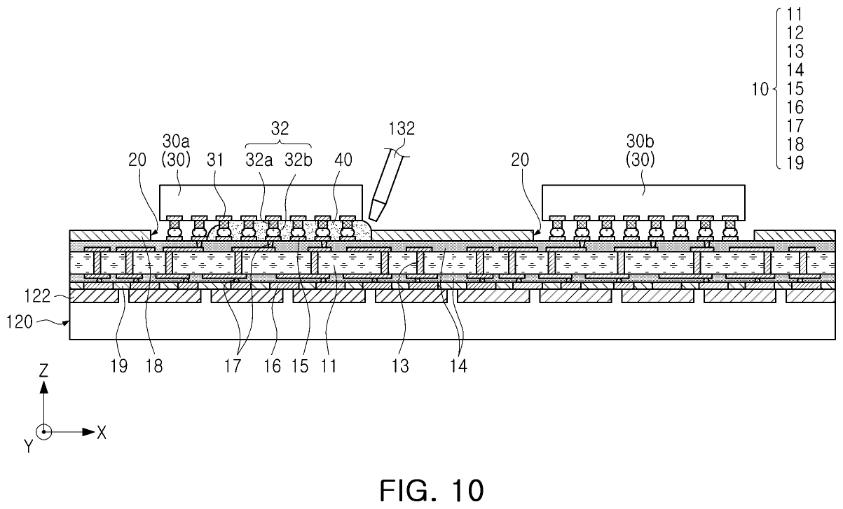

Referring to FIG. 6 and FIG. 10, the dispensing nozzle 132 may discharge the underfill 40 to the bonding areas 20 of the substrate 10 (S150). The underfill 40 may flow under the semiconductor chips 30 by capillary phenomenon or capillary action. The underfill 40 may fill the space between the substrate 10 and the first semiconductor chip 30a and between the substrate 10 and the second semiconductor chip 30b. The underfill 40 may include an insulating polymer material, for example, an epoxy resin.

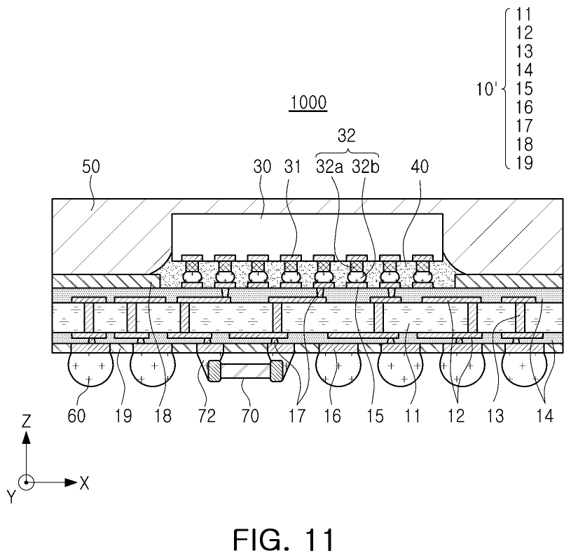

Referring to FIG. 11, an encapsulant 50 covering the substrate 10 and the semiconductor chips 30 may be formed, and an external connection terminal 60 and a passive component 70 may be formed on the lower surface of the substrate 10 to manufacture a semiconductor package 1000. The substrate 10 may be separated along scribe lanes to form a package substrate 10′.

The encapsulant 50 may be a resin including epoxy or polyimide. For example, the resin may include a bisphenol-group epoxy resin, a polycyclic aromatic epoxy resin, an o-Cresol Novolac epoxy resin, a biphenyl-group epoxy resin, or a naphthalene-group epoxy resin.

The external connection terminal 60 may be disposed on the lower surface of the substrate 10. The external connection terminal 60 may be in contact with the lower pad 16 disposed on the lower surface of the substrate 10. A ground voltage (Vss) or a power supply voltage (Vdd) may be applied to the lower pad 16. The external connection terminal 60 may be electrically connected to an external device such as a main board. The external connection terminal 60 may include a conductive material and may have a ball, pin, or lead shape. For example, the external connection terminal 60 may be a solder ball.

The passive component 70 may be electrically connected to a corresponding one of the lower pads 16 through the connection terminal 72. The passive component 70 may include, for example, a capacitor such as a Multilayer Ceramic Capacitor (MLCC) or a Low Inductance Chip Capacitor (LICC), an inductor, a bead, and the like. In an example embodiment, the passive component 70 is a Land-Side Capacitor (LSC). However, the present inventive concept is not limited thereto, and according to an example embodiment, the passive component 70 may be a Die-Side Capacitor (DSC) mounted on the upper surface of the substrate 10 or an embedded type capacitor built into the interior of the substrate 10.

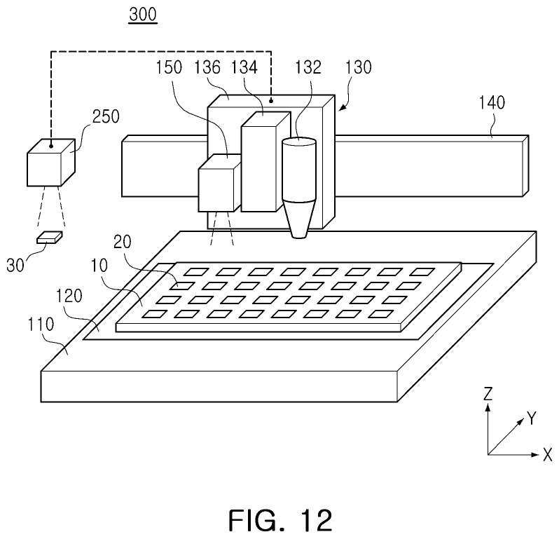

FIG. 12 is a schematic perspective view of an underfill dispensing system according to an example embodiment.

Referring to FIG. 12, the underfill dispensing system 200 further includes an imaging device 250. In an example embodiment, the imaging device 250 may be configured to capture image of a semiconductor chip 30. For example, the imaging device 250 may capture image of a bump structure 32 disposed on a lower surface of the semiconductor chip 30. While the imaging device 250 is illustrated as not being mounted on the dispensing head 130, embodiments are not limited thereto. The imaging device 250 may be commutatively connected to the control unit 160 and may transmit and receive electrical signals and/or data signals with the control unit 160. In an example embodiment, the imaging device 250 is omitted, and the imaging device 150 may be configured to capture images of both the bonding areas 20 and the semiconductor chips 30.

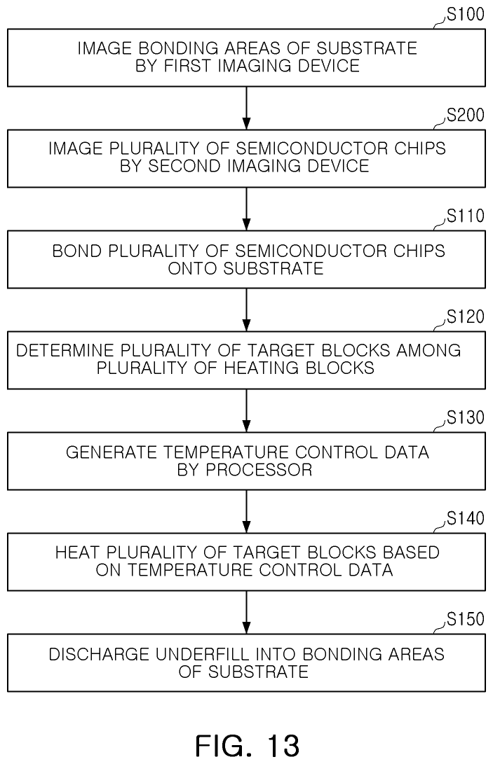

FIG. 13 is a flow chart illustrating an underfill dispensing method according to an example embodiment. FIG. 13 is a drawing illustrating an underfill dispensing method using the underfill dispensing system illustrated in FIG. 12.

Referring to FIG. 13, an underfill dispensing method according to an example embodiment may include a first imaging device 150 imaging bonding areas 20 of a substrate 10 (S100), a second imaging device 250 imaging a plurality of semiconductor chips 30 (S200), bonding a plurality of semiconductor chips on the substrate 10 (S110), determining a plurality of target blocks 124 among a plurality of heating blocks 122 (S120), a processor 170 generating temperature control data (S130), heating the plurality of target blocks 124 based on the temperature control data (S140), and discharging underfill into the bonding areas 20 of the substrate 10 (S150).

As described above, the imaging device 150 may capture first images of the bonding areas 20 of the substrate 10. The first images may be transmitted to the processor 170 and/or the memory unit 180. At least one of the first images may be used to determine the target blocks 124. The second imaging device 250 may capture second images of the bump structure 32

disposed on the lower surface of the semiconductor chip 30. The second images may be transmitted to the processor 170 and/or the memory unit 180. The second images may be used to generate temperature control data. For example, the control unit 160 may control the processor 170 to generate temperature control data based on at least one of the second images. The processor 170 may generate temperature control data based on the shape of the bump structure 32 of the semiconductor chip 30 illustrated in the second image, the pattern density, the gap between the bump structures 32, or the like.

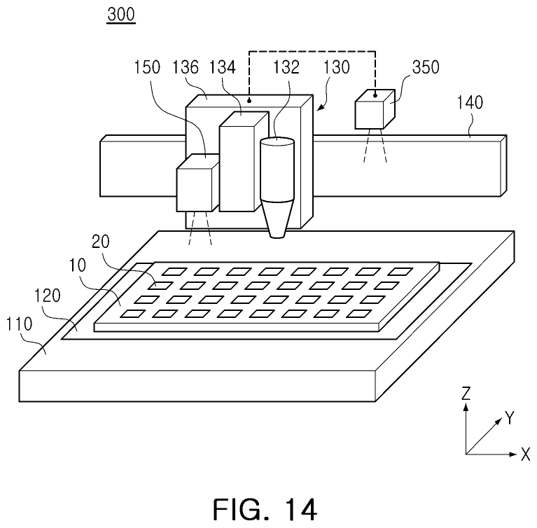

FIG. 14 is a schematic perspective view of an underfill dispensing system according to an example embodiment.

Referring to FIG. 14, the underfill dispensing system 300 further includes an imaging device 350. In an example embodiment, the imaging device 350 may be configured to capture an image of the substrate 10 after the process of discharging the underfill (S150).

The process of discharging the underfill 40 (S150) may be sequentially performed on the bonding areas 20 on the substrate 10. The imaging device 350 may image the substrate 10 to confirm whether the process of forming the underfill 40 for the semiconductor chip 30 bonded on respective bonding areas 20 has completed. If it is confirmed that the process of forming the underfill 40 has completed, the processor 170 may stop heating the target block 124.

For example, the first and second semiconductor chips 30 may be bonded on the first and second bonding areas 20, respectively, and after the process of discharging the underfill 40 to the first semiconductor chip 30 has been performed, the process of discharging the underfill 40 to the second semiconductor chip 30 may be performed. The imaging device 350 may capture images of the substrate 10, and the processor 170 may sequentially stop heating target blocks 124 corresponding to the first semiconductor chip 30 and may stop heating target blocks 124 corresponding to the second semiconductor chip 30.

In an example embodiment, the processor 170 may sequentially start heating target blocks 124 corresponding to respective semiconductor chips 30.

As set forth above, according to example embodiments, by heating the heating blocks to a relatively high temperature (e.g., higher than an upper threshold) in an area in which a pattern density of an upper pad of a substrate or a bump structure of a semiconductor chip is high, an underfill dispensing process time may be shortened and productivity may be increased. By heating the heating blocks to a relatively low temperature (e.g., lower than a lower threshold that is less than the upper threshold) in an area in which the pattern density of an upper pad of a substrate or a bump structure of a semiconductor chip is low, generation of voids in the underfill may be prevented.

While example embodiments have been illustrated and described above, it will be apparent to those skilled in the art that modifications and variations could be made without departing from the scope of the present inventive concept as defined by the appended claims.

What is claimed is:

1. An underfill dispensing system comprising:
a substrate table configured to support a substrate including a plurality of bonding areas for mounting a plurality of semiconductor chips;
a heating structure disposed on an upper surface of the substrate table and including a plurality of heating blocks;
a dispensing head configured to dispense underfill to the plurality of bonding areas of the substrate, above the substrate table;
an imaging device; and
a control unit configured to control the heating structure and the dispensing head,
wherein the imaging device is configured to image at least one of the substrate and the plurality of semiconductor chips to generate an image, and
wherein the control unit is configured to control the plurality of heating blocks independently of one another based on the image.

2. The underfill dispensing system of claim 1, further including a processor configured to generate temperature control data based on the image.

3. The underfill dispensing system of claim 1, wherein the imaging device is configured to image the plurality of bonding areas.

4. The underfill dispensing system of claim 3, wherein the imaging device is mounted on the dispensing head.

5. The underfill dispensing system of claim 1, wherein the heating structure further includes at least one power source supplying power to the plurality of heating blocks and wires connecting the at least one power source and the plurality of heating blocks,
wherein the at least one power source, the wires, and the plurality of heating blocks form heating circuits, and
wherein the control unit controls the heating circuits independently of one another.

6. The underfill dispensing system of claim 1, wherein the plurality of heating blocks respectively include a metal structure that includes at least one of Platinum (Pt), Aluminum (Al), Copper (Cu), Gold (Au), Silver (Ag), and Nickel (Ni).

7. The underfill dispensing system of claim 1, further including a processor configured to determine a plurality of target blocks overlapping the plurality of semiconductor chips, among the plurality of heating blocks, and
the control unit is configured to heat the plurality of target blocks based on temperature control data.

8. The underfill dispensing system of claim 7, wherein determining the plurality of target blocks includes comparing positions of the plurality of heating blocks stored in a memory with positions of the plurality of bonding areas in the image.

9. The underfill dispensing system of claim 8, wherein the plurality of target blocks include a first target block and a second target block, and
wherein the control unit to heat the first target block to a higher temperature than a temperature of the second target block when a pattern density of upper pads of the substrate corresponding to the first target block is higher than a pattern density of upper pads of the substrate corresponding to the second target block.

10. The underfill dispensing system of claim 9, wherein the processor is configured to determine a plurality of peripheral blocks disposed to surround the plurality of target blocks among the plurality of heating blocks, and
the control unit is configured to heat the plurality of peripheral blocks.

11. The underfill dispensing system of claim 10, wherein the plurality of peripheral blocks are heated to the same temperature.

12. The underfill dispensing system of claim 1, further comprising a memory that stores a machine learning model that processes the image for generating temperature control data and the control unit is configured to control the plurality of heating blocks independently of one another based on the temperature control data.

13. The underfill dispensing system of claim 1, wherein the imaging device is configured to image the plurality of semiconductor chips.

14. The underfill dispensing system of claim 1, wherein the plurality of semiconductor chips include a first semiconductor chip and a second semiconductor chip, and
a number of the heating blocks corresponding to the first semiconductor chip is different from a number of the heating blocks corresponding to the second semiconductor chip.

15. An underfill dispensing system comprising:
a substrate table configured to support a substrate including a plurality of bonding areas for mounting a plurality of semiconductor chips;
a heating structure disposed on an upper surface of the substrate table and including a plurality of heating blocks;
a dispensing head configured to dispense underfill to the plurality of bonding areas of the substrate, above the substrate table;
a processor;
a first imaging device connected to the processor and configured to capture a first image of the substrate;
a second imaging device connected to the processor and configured to capture a second image of at least one of the plurality of semiconductor chips; and
a control unit configured to control the heating structure, the dispensing head, and the processor,
wherein the processor is configured to generate temperature control data based on the first image and the second image, and
wherein the control unit controls the plurality of heating blocks independently from one another using the temperature control data.

16. The underfill dispensing system of claim 15, wherein the first imaging device is configured to image the plurality of bonding areas of the substrate to generate the first image, and
the second imaging device is configured to image bump structures of the plurality of semiconductor chips to generate the second image.

17. The underfill dispensing system of claim 16, wherein the first image and the second image are transmitted to the processor.

18. The underfill dispensing system of claim 16, wherein the processor determines a plurality of target blocks overlapping the plurality of semiconductor chips among the plurality of heating blocks based on the first image, and is configured to generate the temperature control data based on the second image.

19. An underfill dispensing system comprising:
a substrate table configured to support a substrate including a plurality of bonding areas for mounting a plurality of semiconductor chips;
a heating structure disposed on an upper surface of the substrate table and including a plurality of heating blocks arranged in a grid pattern;
a dispensing head configured to dispense underfill to a plurality of bonding areas of the substrate, above the substrate table;
a processor;
an imaging device connected to the processor; and
a control unit configured to control the heating structure, the dispensing head, and the processor,
wherein the dispensing head includes a dispensing nozzle for discharging the underfill, an underfill reservoir configured to supply the underfill to the dispensing nozzle, and a nozzle movement assembly configured to move the dispensing nozzle,
the imaging device is configured to image at least one of the substrate and the plurality of semiconductor chips to generate an image,
the control unit controls the processor to generate temperature control data based on the image and controls the plurality of heating blocks independently from each other using the temperature control data.

20. The underfill dispensing system of claim 19, wherein each of the plurality of heating blocks is smaller than the plurality of semiconductor chips.
